(19) United States
(12) Patent Application Publication
(10) Pub. No.: US 2026/0013097 A1
(43) Pub. Date: Jan. 8, 2026

(54) MOLD STACK FORMATION VIA METAL INDUCED CRYSTALLIZATION

(71) Applicant: Applied Materials, Inc., Santa Clara, CA (US)

(72) Inventors: Chang Seok Kang, Santa Clara, CA (US); Ruiying Hao, San Jose, CA (US); Raghuveer S. Makala, Campbell, CA (US); Tomohiko Kitajima, San Jose, CA (US); Balasubramanian Pranatharthiharan, San Jose, CA (US)

(73) Assignee: Applied Materials, Inc., Santa Clara, CA (US)

(21) Appl. No.: 18/765,048

(22) Filed: Jul. 5, 2024

(51) Int. Cl. H10B 12/00

(52) U.S. Cl. CPC H10B 12/01

(57) ABSTRACT

Embodiments of the present technology may include semiconductor processing methods and systems, such as methods and systems for processing 3D DRAM devices. Methods and systems include depositing a plurality of layers of amorphous or poly-crystalline material over a substrate, forming a film stack. Methods include depositing a metal seed layer adjacent and parallel to an outer surface of the plurality of layers. Methods include annealing the plurality of unit stacks, driving the metal seed layer in a direction generally perpendicular to the plurality of layers of amorphous or poly-crystalline material, and removing the metal seed layer.

### TECHNICAL FIELD

The present technology relates to semiconductor systems and processes. More specifically, the present technology relates to three-dimensional (3D) dynamic random-access memory (DRAM) devices (3D DRAM), and methods of forming such devices.

### BACKGROUND

Integrated circuits are made possible by processes which produce intricately patterned material layers on substrate surfaces. Producing patterned material on a substrate requires controlled methods of formation and removal of exposed material. Material characteristics may affect how the device operates, and may also affect how the films are removed relative to one another. During formation and removal, materials may be subject to unintended stress, which may result in defects within the device. Such defects within a device becomes increasing problematic as devices continue to shrink.

Thus, there is a need for improved systems and methods that can be used to produce high quality devices and structures. These and other needs are addressed by the present technology.

### SUMMARY

The present technology is generally directed to methods for producing and/or processing 3D-DRAM structures. Methods include depositing a plurality of layers of amorphous or poly-crystalline material over a substrate, forming a film stack. Methods include depositing a metal seed layer adjacent and parallel to an outer surface of the plurality of layers. Methods include annealing the film stack, driving the metal seed layer in a direction generally perpendicular to the plurality of layers of amorphous or poly-crystalline material, and removing the metal seed layer.

In embodiments, the film stack includes alternating layers of a channel material and a sacrificial material. Furthermore, in embodiments, the film stack includes one or more layers of doped or undoped silicon, carbon, or combinations thereof. In more embodiments, the film stack includes one or more layers of a dielectric material. Additionally or alternatively, in embodiments, the dielectric material includes silicon oxide, silicon nitride, doped or undoped silicon germanium, or a combination thereof. Moreover, in embodiments, methods further include depositing a capping layer over a top surface of the film stack. In embodiments, the metal seed layer is deposited between the substrate and a first layer of the plurality of layers of amorphous or poly-crystalline material. In yet more embodiments, methods include a capping layer disposed over a last layer of the plurality of layers of amorphous or poly-crystalline material, where the capping layer includes a gettering layer. Embodiments include where the metal seed layer is deposited over a last layer of the plurality of layers of amorphous or poly-crystalline material. In further embodiments, the substrate includes a gettering layer. Moreover, in embodiments, methods include removing the substrate and any seed metal contained in or adjacent to the substrate after annealing, exposing a lower surface of the film stack. Embodiments include bonding a peripheral component to the lower surface. In embodiments, methods include flipping an orientation of the film stack, where the lower surface is disposed above an upper surface, prior to removing the substrate. Furthermore, in embodiments, methods include bonding a secondary substrate to an upper surface of the film stack prior to flipping the orientation of the film stack. In more embodiments, the metal seed layer is deposited at a thickness of about 1 Å to about 100 Å.

The present technology is also generally directed to 3D DRAM semiconductor processing methods. Methods include depositing a plurality of layers of amorphous or poly-crystalline material over a substrate, forming a film stack. Methods include depositing a metal seed layer adjacent and parallel to an outer surface of the plurality of layers. Methods include depositing a capping layer over the film stack. Methods include annealing the film, driving the metal seed layer in a direction generally perpendicular to the plurality of layers of amorphous or poly-crystalline material, and removing the metal seed layer.

In embodiments, the metal seed layer is deposited between the substrate and a first layer of the plurality of layers, or over a last layer of the plurality of layers. Moreover, in embodiments, at least one of the capping layer and the substrate includes a gettering layer.

The present technology is also generally directed to methods of forming a three-dimensional dynamic random-access memory (3D DRAM) device. Methods include providing a substrate to a processing region of a semiconductor processing chamber. Methods include depositing a plurality of alternating pairs of an amorphous or poly-crystalline silicon-containing material layer and a silicon-and-germanium-containing material layer over the substrate, forming a film stack. Methods include depositing a metal seed layer adjacent and parallel to an outer surface of the plurality of alternating pairs. Methods include depositing a capping layer over the film stack. Methods include annealing the film, driving the metal seed layer in a direction generally perpendicular to the plurality of alternating pairs, and removing the metal seed layer. In embodiments, the metal seed layer is deposited between the substrate and a first pair of alternating pairs, or over a pair of alternating pairs, and at least one of the capping layer and the substrate comprise a gettering layer.

Such technology may provide numerous benefits over conventional systems and methods of forming 3D-DRAM devices. For example, by forming devices as discussed herein, little to no lattice mismatch may exist after the formation of the mold stack. Thus, devices and methods discussed herein may provide reduced defects, and increased stability. Embodiments of the present technology, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a top plan view of an exemplary processing system according to some embodiments of the present technology.

FIG. 1B shows a schematic cross-sectional view of an exemplary processing system according to some embodiments of the present technology.

FIG. 2 shows operations of an exemplary method of semiconductor processing according to some embodiments of the present technology.

FIGS. 3A-3G show a cross-sectional views of exemplary semiconductor structures according to some embodiments of the present technology.

FIG. 4 shows operations of an exemplary method of semiconductor processing according to some embodiments of the present technology.

FIGS. 5A-5B show a cross-sectional views of exemplary semiconductor structures according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In dynamic random-access memory (DRAM) devices, such as 3D DRAM, alternating layers of material may be formed on a substrate. The alternating layers of material may include alternating pairs of a channel material, such as a silicon-containing material, and a dielectric material, such as a silicon-and-germanium-containing material. As the number of layers increase, so does the challenge to maintain defect free epitaxial growth and minimized defects. In one example, as the number of layers of channel material and dielectric material increases, defects and bowing are observed, due to the lattice mismatch between the channel material and the dielectric material. If the substrate becomes too bowed, or if too many defects are included, the substrate may break and/or downstream operations may be frustrated. For example, many downstream operations have bow limitations, including deposition, lithography, and etch operations. Accordingly, processes to combat substrate bow and defect inclusion are necessary to perform downstream operations.

Initial efforts to improve 3D DRAM devices included using single crystalline growth methods for forming the mold stack. For instance, epitaxial growth was utilized to form layers of a desired thickness of a channel material and a desired thickness of the dielectric material. However, in order to achieve a desired etch selectivity for eventual removal of the dielectric material, the lattice of the dielectric material increasingly mismatched from the lattice of the channel material. Thus, even with advanced growth techniques, mold stacks exhibited undesirable lattice mismatch, leading to unacceptably high levels of defects and bow.

The present technology overcomes these and other problems by providing embodiments that include forming a mold stack by depositing amorphous or poly-crystalline layers of the channel material and dielectric material, followed by introduction of a nucleating metal to form one or more single crystalline layers. Specifically, embodiments include carefully controlling the deposition of the dielectric layers in combination with a gettering layer to achieve highly crystalline layers (e.g. single crystalline layers) with little to no nucleating metal remaining in the structure. The methods discussed herein may remove any defects formed during growth of the mold stack, improving the electrical properties of the resulting device.

After describing general aspects of a chamber configured to perform operations according to embodiments of the present technology in which plasma processing may be performed, specific methodology and component configurations may be discussed. It is to be understood that the present technology is not intended to be limited to the specific films and processing discussed, as the techniques described may be used to improve a number of film formation processes, and may be applicable to a variety of semiconductor processing chambers and operations.

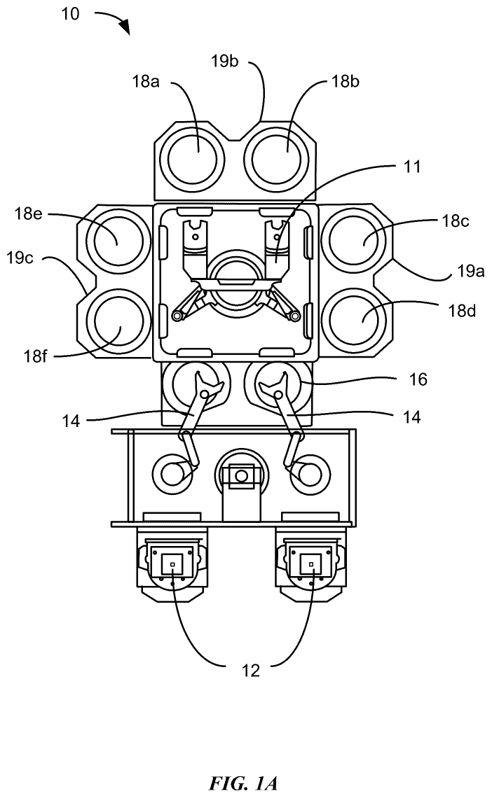

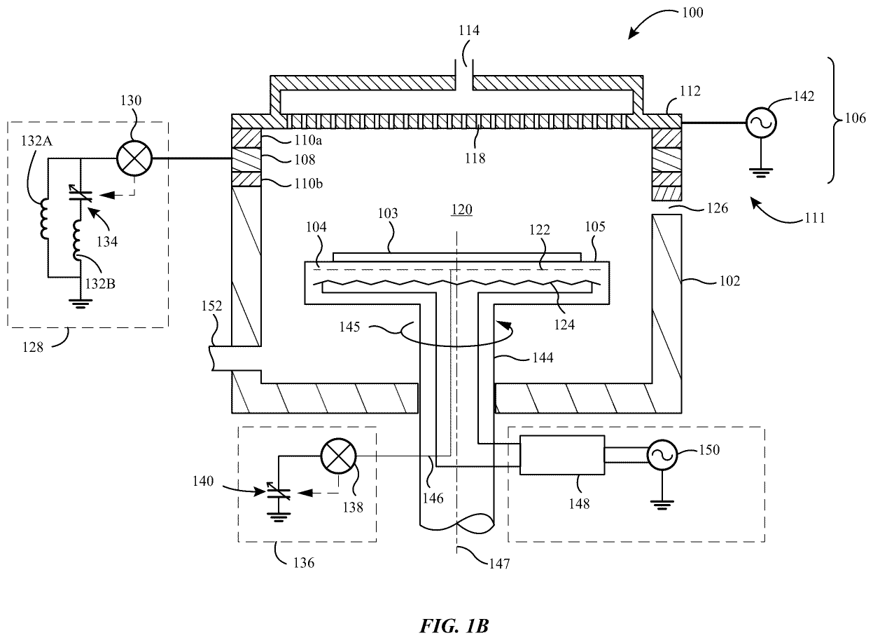

FIG. 1A shows a top plan view of one embodiment of a processing system 10 of deposition, treating, etching, baking, and curing chambers according to embodiments. In the figure, a pair of front opening unified pods 12 supply substrates of a variety of sizes that are received by robotic arms 14 and placed into a low pressure holding area 16 before being placed into one of the semiconductor processing chambers 18a-f, positioned in tandem sections 19a-c. A second robotic arm 11 may be used to transport the substrate wafers from the holding area 16 to the semiconductor processing chambers 18a-f and back. Each semiconductor processing chamber 18a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, plasma treatments, annealing, ashing, etc.

The semiconductor processing chambers 18a-f may include one or more system components for depositing, plasma treating, curing and/or etching a dielectric or other film on the substrate. In one configuration, two pairs of the semiconductor processing chambers, e.g., 18c-d and 18e-f, may be used to deposit dielectric material on the substrate, and the third pair of semiconductor processing chambers, e.g., 18a-b, may be used to treat the deposited dielectric. In another configuration, all three pairs of chambers, e.g., 18a-f, may be configured to deposit and treat stacks of alternating dielectric films on the substrate. Any one or more of the processes described may be carried out in chambers separated from the fabrication system shown in different embodiments. It will be appreciated that additional configurations of deposition, treating, etching, annealing, and curing chambers for dielectric films are contemplated by system 10.

FIG. 1B shows a cross-sectional view of an exemplary semiconductor processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form tensile nitride films according to some embodiments of the present technology, although it is to be understood that the methods may similarly be performed in any chamber within which film formation may occur. The semiconductor processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the semiconductor processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the semiconductor processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the semiconductor processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1B, or the gas distributor 112 may be coupled with ground in some embodiments.

The first electrode 108 may be coupled with a first tuning circuit 128 that may control a ground pathway of the semiconductor processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1B may be used with any semiconductor processing chamber for plasma or thermal processing. In operation, the semiconductor processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the semiconductor processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

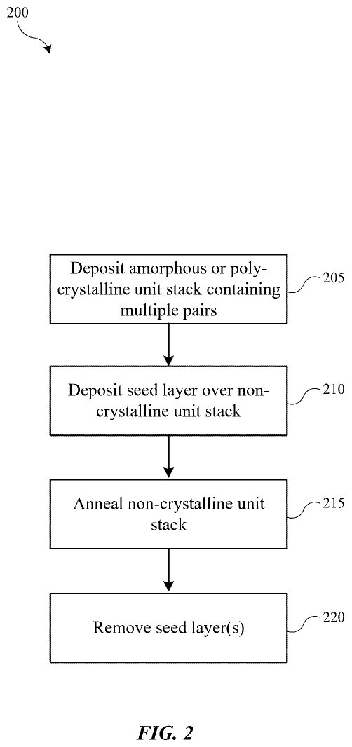

FIG. 2 shows exemplary operations in a method 200 for forming a semiconductor structure according to embodiments of the present technology. Method 200 may include one or more operations prior to the initiation of the method, including front-end processing, deposition, etching, polishing, cleaning, or any other operations that may be performed prior to the described operations. For example, the method may begin after a number of layers have been deposited, such as for producing 3D DRAM structures. However, as explained above, it is to be understood that the figures illustrate just one exemplary process in which processes according to embodiments of the present technology may be employed, and the description is not intended to limit the technology to this process or structure alone. Some or all of the operations may be performed in chambers or system tools as previously described, or may be performed in different chambers on the same system tool, which may include the chamber in which the operations of method 200 may be performed.

Method 200 may include additional operations prior to initiation of the listed operations. For example, additional processing operations may include forming structures on a substrate, which may include both forming and removing material. Prior processing operations may be performed in the chamber in which method 200 may be performed, or processing may be performed in one or more other semiconductor processing chambers prior to delivering the substrate into the semiconductor processing chamber in which method 200 may be performed. Regardless, method 200 may optionally include delivering a substrate to a processing region of a semiconductor processing chamber, such as semiconductor processing chamber 100 described above, or other chambers that may include components as described above. The substrate may be deposited on a substrate support, which may be a pedestal such as substrate support 104, and which may reside in a processing region of the chamber, such as processing volume 120 described above. Method 200 describes operations shown schematically in the Figures, the illustrations of which will be described in conjunction with the operations of method 200. It is to be understood that the Figures illustrate only partial schematic views, and a substrate may contain any number of structural sections having aspects as illustrated in the figures, as well as alternative structural aspects that may still benefit from operations of the present technology.

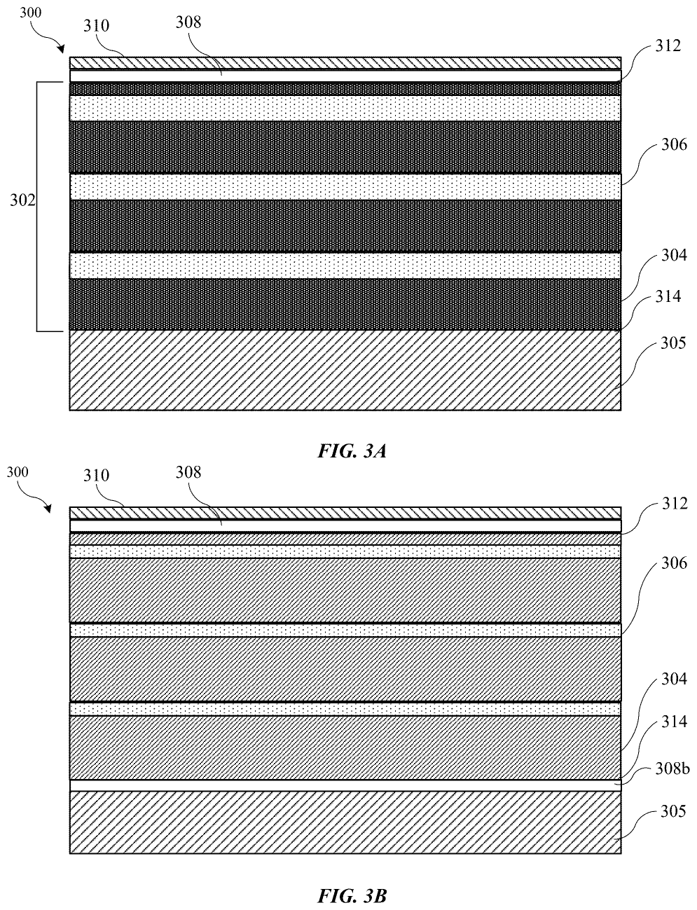

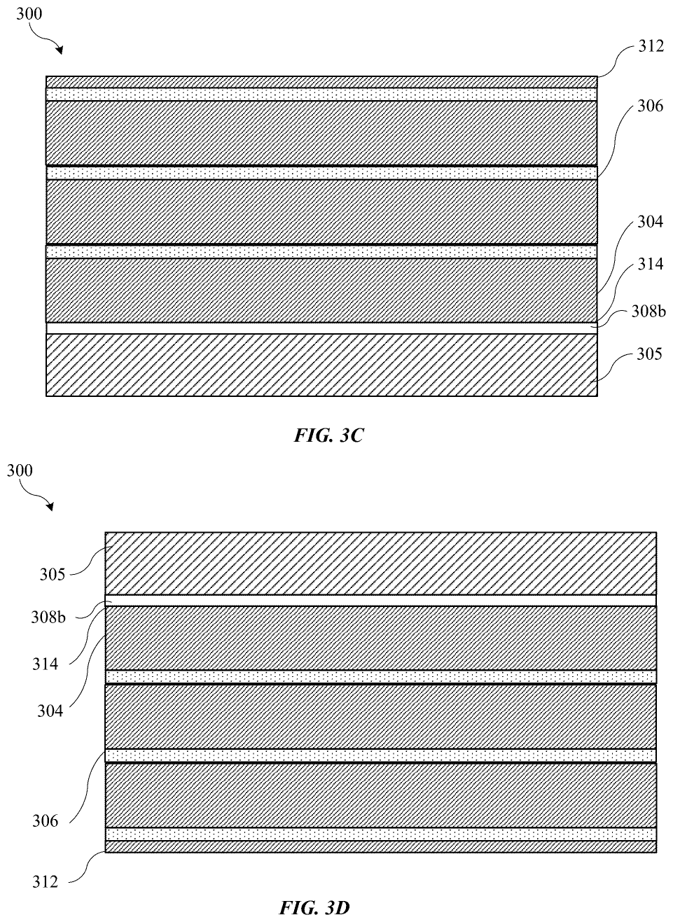

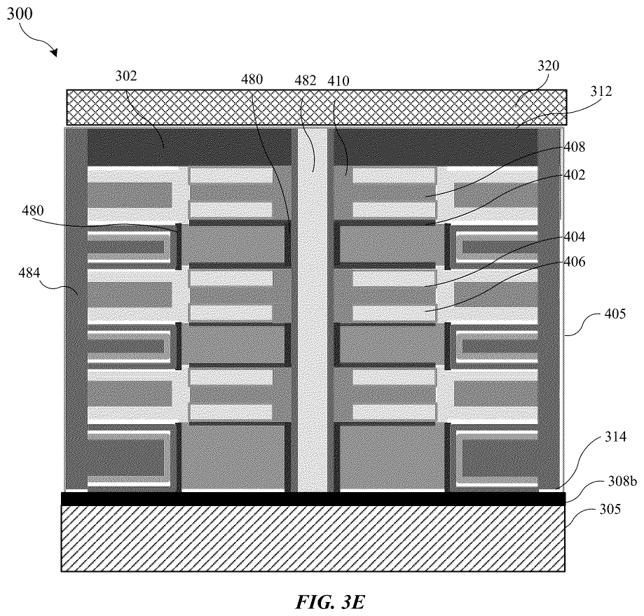

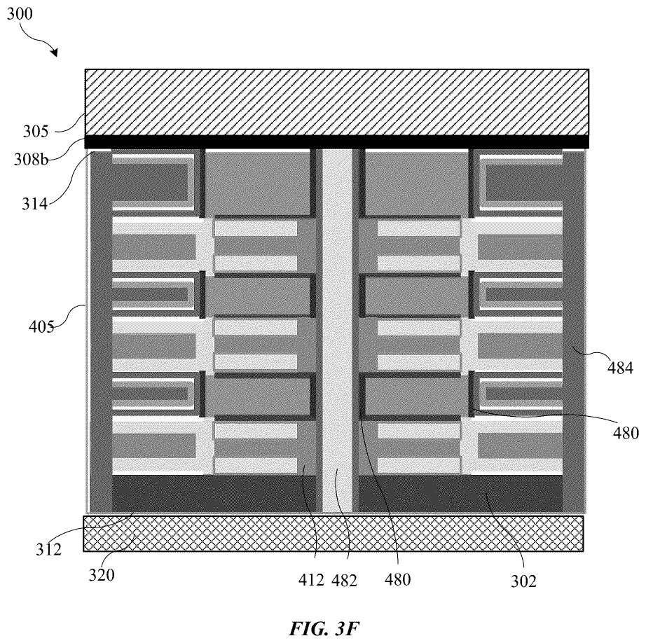

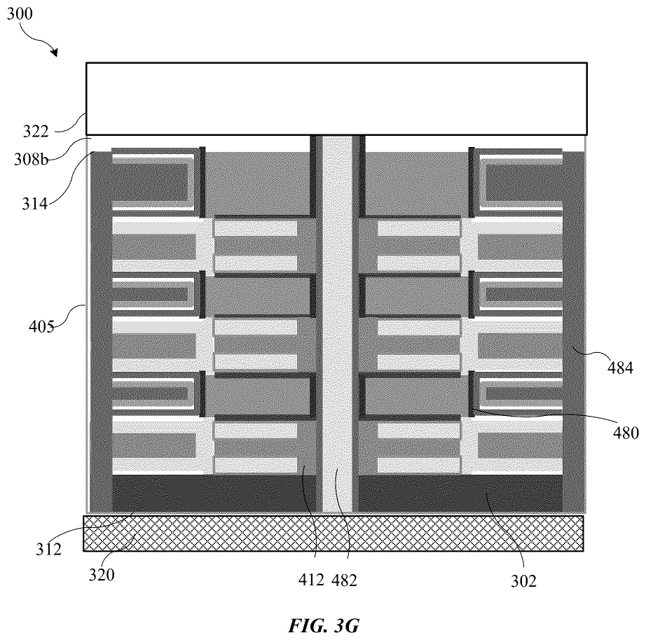

Nonetheless, as illustrated in FIG. 3A, operation 205 may include depositing an amorphous or poly-crystalline film stack 302 over a substrate 305, at operation 205. As illustrated, the amorphous or poly-crystalline film stack 302 includes alternating layers of a channel material 304 and a sacrificial material 306. Regardless of the materials utilized or the number of pairs, advantageously, the embodiments discussed herein include depositing or forming the materials in an amorphous or poly-crystalline form. Thus, in embodiments, operation 205 may include one or more expedient deposition processes, such as physical vapor deposition (PVD) and/or chemical vapor deposition (CVD), as single-crystalline form in the initially formed unit stack 302 is not necessary.

Substrate 305 may be formed from any number of materials, such as a base wafer or substrate made of silicon or silicon-containing materials, germanium, other substrate materials, as well as one or more materials that may be formed overlying the substrate during semiconductor processing. In embodiments, the substrate 305 may include bulk substrates, epitaxially grown substrates, and/or silicon on insulator wafer. As used herein, the term “semiconductor substrate” refers to a substrate in which the entirety of the substrate is formed from a semiconductor material. The semiconductor substrate may include any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the substrate 305 includes a semiconductor material, e.g., silicon (Si), carbon (C), germanium (Ge), silicon germanium (SiGe), germanium tin (GeSn), other semiconductor materials, or any combination thereof. In one or more embodiments, the substrate 305 includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the substrate 305 may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

Nonetheless, in embodiments, substrate 305 may serve as a gettering layer. Thus, in embodiments, substrate 305 may include one or more of the above materials, but may be initially formed or provided having a plurality of defects, or gettering sites, such as precipitates or dislocations within the substrate 305. For instance, in embodiments, the substrate 305 may be formed, or provided as a substrate formed by an implant process. Alternatively, the substrate 305 may be mechanically altered, or provided in an altered state, such as by sandblasting or grooving, to imbue the necessary stress or dislocations to form the gettering sites.

In embodiments, channel material 304 may be a silicon-containing material or any one or more of the substrate materials discussed above. However, in embodiments, channel material 304 may be doped or undoped silicon. Nonetheless, as discussed above, channel material 304 is deposited in an amorphous or poly-crystalline form. Namely, in embodiments, channel material 304 is deposited as an amorphous material. Furthermore, unlike substrate material 305, the channel material may be deposited in a consistent layer or layers, so as to contain little to no gettering sites. For instance, as discussed above, the channel material may be deposited utilizing CVD or PVD, as well as other methods as known in the art.

Moreover, in embodiments, the alternating layer may be a sacrificial material 306, such as one or more dielectric materials. In embodiments, the sacrificial material may be any dielectric material that may be selectively etched as compared to the channel material. In embodiments, the dielectric material may include a silicon-and-germanium-containing material, silicon oxide, silicon nitride, silicon oxynitride, SiOC, SiCN, SiOCN, as well as combinations thereof. Regardless of the material selected, as discussed in regards to the channel material 304, and unlike substrate material 305, the sacrificial material 306 may be deposited in a consistent layer or layers, so as to contain little to no gettering sites. For instance, as discussed above, the channel material may be deposited utilizing CVD or PVD, as well as other methods as known in the art.

In embodiments, the sacrificial material may include a silicon germanium material. In embodiments where the sacrificial material is SiGe, the germanium content may range from about 1% to about 50% by weight of the layer without negatively impacting the structural integrity of the device, such as less than or about 45%, such as less than or about 40%, such as less than or about 35%, such as less than or about 30%, such as less than or about 25%, such as less than or about 20%, such as less than or about 15%, such as less than or about 10%, such as less than or about 5%, or such as greater than or about 2.5%, such as greater than or about 5%, such as greater than or about 7.5%, such as greater than or about 10%, such as greater than or about 15%, such as greater than or about 20%, such as greater than or about 25%, such as greater than or about 30%, such as greater than or about 35%, such as greater than or about 40%, such as greater than or about 45%, or any ranges or values therebetween. Namely, as the instability of the lattice is addressed after formation of the unit stack, it may be possible to include higher levels of germanium in the sacrificial material.

Nonetheless, the channel material 304 and sacrificial material 306 may be deposited in an alternating fashion, where a layer of channel material 304 together with a layer of sacrificial material 306 may be considered a “pair”, with multiple pairs, units, or layers forming film stack 302. The film stack 302 may include multiple unit stacks or pairs (e.g., three unit stacks in the illustrated example, however, it should be clear that more pairs are contemplated herein, as discussed below) that are, in part, used sacrificially to form 3D DRAM cells. As will become apparent, this illustration shows three layers of 3D DRAM cells. In other examples, repeating the unit stacks of the film stack can enable forming additional layers of 3D DRAM cells. Also, using one instance of the unit stack in the film stack can enable forming one layer of 3D DRAM cells.

In embodiments, the present technology has found that the methods herein are well suited for forming large numbers of unit stacks. Namely, the present technology has found that by initially depositing the unit stacks as amorphous or poly-crystalline materials, and then crystallizing at least the channel material into a single crystalline material, little to no defects remain in the film stack 302 after crystallization, allowing for increased pairs without problematic instability. In embodiments, the film stack 302 may include greater than or about 20 alternating pairs of the channel material 304 and sacrificial material 306, such as greater than or about 30 alternating pairs, such as greater than or about 40 alternating pairs, such as greater than or about 50 alternating pairs, such as greater than or about 60 alternating pairs, such as greater than or about 70 alternating pairs, such as greater than or about 80 alternating pairs, such as greater than or about 90 alternating pairs, greater than or about 100 alternating pairs, greater than or about 110 alternating pairs, greater than or about 120 alternating pairs, greater than or about 130 alternating pairs, greater than or about 140 alternating pairs, greater than or about 150 alternating pairs, greater than or about 160 alternating pairs, greater than or about 170 alternating pairs, greater than or about 180 alternating pairs, greater than or about 190 alternating pairs, greater than or about 200 alternating pairs, greater than or about 250 alternating pairs, greater than or about 500 alternating pairs, greater than or about 750 alternating pairs, up to about 1000 alternating pairs, or more, or any ranges or values therebetween.

A thickness of each unit pair of the alternating pairs, such as the channel material 304 and sacrificial material 306 may be greater than or about 30 nm. In such a manner, adequate space for accommodating insulator volume is provided. Thus, in embodiments, each pair may have a thickness that is greater than or about 35 nm, such as greater than or about 40 nm, greater than or about 45 nm, greater than or about 50 nm, greater than or about 55 nm, greater than or about 60 nm, greater than or about 65 nm, greater than or about 70 nm, greater than or about 75 nm, greater than or about 80 nm, greater than or about 85 nm, greater than or about 90 nm, greater than or about 95 nm, greater than or about 100 nm, or any ranges or values therebetween.

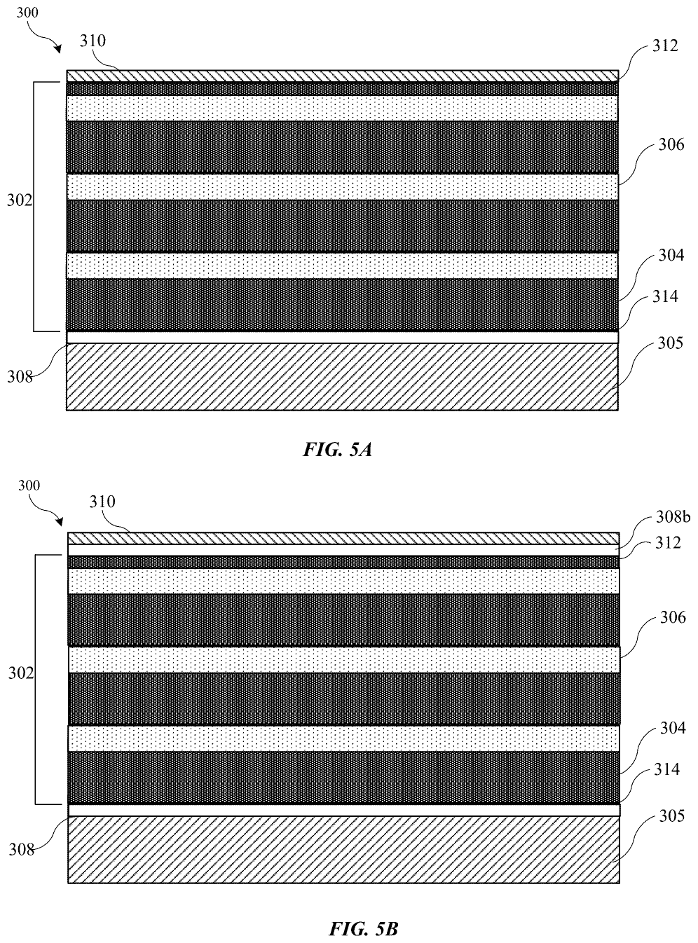

Methods of the present technology include depositing a metal seed layer 308 adjacent to, such as directly adjacent in embodiments, one or more outer surfaces of the film stack 302, such as a top surface 312 or a bottom surface 314 of the film stack, at operation 210. Namely, even though bottom surface 314 is adjacent to substrate 305, bottom surface 314 still forms an outer side of the film stack 302. FIG. 3A illustrates where a metal seed layer 308 is disposed over a top surface 312 of the film stack (e.g. over a last layer of the unit stacks, moving from the substrate in the growth direction), such as over some or all of a top surface of the film stack. Namely, in embodiments, the seed layer may be applied over or adjacent to the film stack as a layer or layers that run in a direction generally parallel to top surface or bottom surface of the film stack, such that the deposited layer is formed generally parallel to one or more of the unit stacks or layers thereof. However, as will be discussed in regards to FIGS. 5A and 5B, it should be clear that other orientations are contemplated. Nonetheless, in embodiments, the metal seed layer 308 may be one or more metals suitable for creating nucleation sites in or on a channel material, such as a silicon material. Thus, in embodiments, the metal seed layer may include nickel (Ni), chromium (Cr), cobalt (Co), palladium (Pd), germanium (Ge), aluminum (Al), tungsten (W), or combinations thereof. In embodiments, the metal seed layer may be or include nickel.

However, regardless of the metal seed layer material selected, the present technology has found that even small amounts of the metal seed layer are sufficient to fully crystallize the amorphous or poly-crystalline film stack into a single crystal form. In embodiments, the term “fully crystallize” or “single crystal” refers to a material that has greater than or equal to about 50%, 60%, 70%, 80%, 90%, 95% or 98% of the crystals oriented in the same direction relative to each other. Thus, in embodiments, the metal seed layer may be formed, such as by deposition according to one or more of the methods discussed above, at a thickness or depth of about 1 Å, such as greater than or about 5 Å, greater than or about 10 Å, greater than or about 15 Å, greater than or about 20 Å, greater than or about 25 Å, greater than or about 30 Å, greater than or about 35 Å, greater than or about 40 Å, greater than or about 45 Å, greater than or about 50 Å, greater than or about 55 Å, greater than or about 60 Å, greater than or about 65 Å, greater than or about 70 Å, greater than or about 75 Å, or such as less than or about 100 Å, less than or about 95 Å, less than or about 90 Å, less than or about 85 Å, less than or about 80 Å, less than or about 75 Å, or any ranges or values therebetween. Namely, the present technology has found that very little of the metal is necessary to nucleate the crystallization of the channel material, and that the metal seed layer is not consumed during the nucleation. However, in embodiments, it may be desired to utilize larger amounts or thicknesses of the metal seed layer.

In embodiments, a capping layer 310 is formed over the film stack, including the metal seed layer 308. The capping layer 310 may contain the metal seed layer 308 against the film stack 302, and may also serve to prevent contamination of the chamber or of the semiconductor structure 300 from the metal seed layer 308 during processing. In embodiments, the capping layer 310 may be any suitable sacrificial material, such as any one or more of the dielectric materials discussed above. Namely, the capping layer may be removed, such as by grinding or polishing, and may therefore not form part of the final structure.

Regardless of whether a capping layer is utilized, the structure may be annealed at operation 215. Namely, as illustrated in FIG. 3B, the annealing operation 215 drives the metal seed layer 308 through the pairs of layers in a direction generally perpendicular to the film stack 302, towards substrate 305, nucleating the crystallization process. Thus, all or a portion of the metal 308b of the metal seed layer 308 may become trapped in the substrate 305 after nucleating the crystallization process, allowing for removal of the metal of the metal seed layer 308 and seed metal 308b after completion of the crystallization of the amorphous or poly-crystalline materials. Moreover, due to the low levels of metal seed layer utilized, and crystallization of the channel layers 304, as illustrated by the change in pattern of channel layers 304, little to no seed metal remains in the channel layers 304 subsequent to the anneal process. Thus, the film stack 302 may now include one or more single-crystalline materials or layers, with little to no defects, and with minimal to no seed metal contamination.

Annealing the semiconductor structure 300 can be accomplished by any suitable technique known in the art. For example, annealing can occur in a temperature range of about 300° C. to about 700° C., in an inert atmosphere, such as greater than or about 325° C., greater than or about 350° C., greater than or about 375° C., greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., greater than or about 625° C., greater than or about 650° C., greater than or about 675° C., or such as less than or about 800° C., less than or about 750° C., less than or about 700° C., less than or about 650° C., less than or about 600° C., less than or about 550° C., less than or about 500° C., or any ranges or values therebetween.

In embodiments, the annealing operation may be conducted for a period of time sufficient to fully crystalize the amorphous and/or poly-crystalline material layers. Thus, the annealing operation may be conducted until the seed metal has fully traversed the film stack 302 from the metal seed layer 308 to one or more gettering layers.

As illustrated in FIG. 3C, in embodiments, after the annealing operation, the capping layer 310 and any remaining metal seed layer 308 may be removed. The capping layer 310 and any remaining metal seed layer 308 may be removed by any one or more processes as known in the art, such as grinding, polishing, etching, and the like. By removing the capping layer and any remaining seed layer 308 prior to further processing, contamination may be further suppressed.

FIG. 3D illustrates flipping the semiconductor structure 300 in order to remove the seed metal 308b, such as by polishing or grinding, at operation 220. However, in embodiments, one or more semiconductor components may be formed prior to flipping, as illustrated by FIG. 3E. Namely, in embodiments, one or more 3D DRAM components may be formed from the film stack 302. For instance, in embodiments, gate oxide 402, a diffusion barrier 404 (such as TiN in embodiments), one or more gate metals 406, and one or more isolations 408, as well as one or more insulative dielectric materials 412, forming the capacitor of semiconductor structure 300. In addition, the semiconductor structure 300 may continue with a standard process flow, forming transistor components and the remainder of the 3D DRAM capacitor components, in this example, such as one or more source/drain regions 480, bit line 482 patterning and fill, electrode 484 formation and the like. However, while select capacitor and transistor components have been indicated, it should be clear that the inclusion of other components and processes are contemplated herein.

Nonetheless, as illustrated, the substrate 305 and seed metal 308b may remain adjacent to a bottom surface 314 of the semiconductor structure 300 during processing. Namely, as discussed above, in embodiments, the substrate 305 may serve as a gettering layer, and may trap or contain the seed metal 308b after the seed metal has initiated the crystallization process. Thus, the seed metal 308b may remain sequestered during processing, and may not impact the formation of the one or more components.

In embodiments, a secondary substrate 320 may be glued, taped, or otherwise bonded to the top surface 312, to act as a secondary “substrate” during backside processing, as illustrated by secondary substrate 320 in FIG. 3E. In embodiments, the secondary substrate may include silicon, quartz, sapphire, glass, indium phosphide, plastic and plastic based materials, combinations thereof, and the like. The secondary substrate 320 may contain one or more device components, such as one or more transistors, one or more metal interconnects and lines, one or more control circuits, one or more storage devices, or the like. It may also contain none of such and act purely as structural support. Furthermore, it should be clear that in embodiments, the secondary substrate 320 may be introduced prior to flipping, and may therefore be present in the orientation shown in FIG. 3F after flipping occurs. However, in embodiments, no secondary substrate may be necessary.

As illustrated in FIG. 3F, the present technology may flip the orientation of the substrate prior to removing the seed metal, in embodiments. Namely, as illustrated, bottom surface 314 is now disposed vertically above top surface 312. However, it should be clear that other orientations are contemplated based upon the structure 300. Nonetheless, the operations subsequent to flipping at operation 204 may be considered “backside processing”. Moreover, as illustrated in FIGS. 3F and 3G, after flipping, the new top surface 314 may be exposed by removing the substrate 305 and seed metal 308b. As discussed above, the removal at operation 220 may including grinding and/or polishing, removing the substrate material 305 and the seed metal 308b from the bottom surface 314 and exposing a bottom surface 314 (now the top surface) of the semiconductor structure, as illustrated in FIG. 3F. For instance, the present technology has found that the semiconductor structure 300 contains little to no seed metal after removal of the metal seed layer 308 and seed metal 308b.

After removal of the substrate 305 and seed metal 308b, the new top surface 314 may be bonded to one or more peripheral components 322. The peripheral component may include one or more transistors, one or more metal interconnects and lines, one or more control circuits, one or more storage devices, or the like.

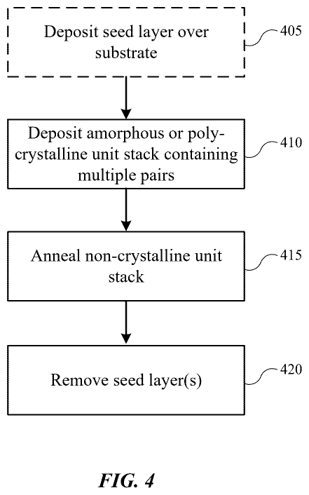

Nonetheless, while so far it has been discussed that the metal seed layer 308 is disposed adjacent to a top surface 312 of the film stack 302 as the outer surface, it should be clear that other orientations are contemplated herein. For instance, referring to FIGS. 4, 5A and 5B, in embodiments, the seed layer may be deposited at operation 405 prior to forming the amorphous or poly-crystalline film stack at operation 410, and therefore be located adjacent to a bottom surface 314. For instance, as illustrated in FIG. 5A, the metal seed layer 308 may be deposited above or on substrate 305 utilizing any one or more of the methods and metals discussed above. Moreover, in embodiments, the substrate 305 may not act as a gettering layer, and may instead be formed or provided in any condition.

After deposition of the metal seed layer 308, the unit stack is formed at operation 410, in the same manner discussed above. However, as illustrated in FIG. 5A, in this orientation, the first formed layer of the film stack 302 is formed over the metal seed layer 308, such as directly over in embodiments. Moreover, in embodiments, capping layer 310 may be formed as a gettering layer. Thus, while capping layer 310 may be or include any one or more of the materials discussed above, in embodiments, capping layer 310 may be initially formed or provided having a plurality of defects, or gettering sites, such as precipitates or dislocations within the capping layer 310. For instance, in embodiments, the capping layer 310 may be formed, or provided as a layer formed by an implant process. Alternatively, the capping layer 310 may be mechanically altered, or provided in an altered state, such as by sandblasting or grooving, to imbue the necessary stress or dislocations to form the gettering sites.

Nevertheless, after formation of the capping layer 310, the semiconductor structure 300 may be annealed at operation 415. In embodiments, the annealing operation may be conducted according to any of the times and temperatures discussed above. Namely, as discussed above, the annealing operation 415 drives the metal seed layer 308 through the pairs of layers in a direction generally perpendicular to the film stack 302, towards capping layer 310, nucleating the crystallization process. Thus, all or a portion of the metal 308b of the metal seed layer 308 may become trapped in the capping layer 310 after nucleating the crystallization process, allowing for removal of the metal of the metal seed layer 308 and seed metal 308b after completion of the crystallization of the amorphous or poly-crystalline materials during subsequent processing. Moreover, due to the low levels of metal seed layer utilized, and crystallization of the channel layers 304, as illustrated by the change in pattern of channel layers 304, little to no seed metal remains in the channel layers 304 subsequent to the anneal process. Thus, the film stack 302 may now include one or more single-crystalline materials or layers, with little to no defects, and with minimal to no seed metal contamination.

The semiconductor structure 300 may then undergo removal of the seed metal 308b and metal seed layer 308 in the same, but opposite manner as discussed above. For instance, the structure of FIG. 5B may re-enter a processing flow, such as the processing flow discussed above, in embodiments, at FIG. 3E.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included. “About” and/or “approximately” as used herein and in the appended claims when referring to a measurable value such as an amount, a temporal duration, and the like, encompasses variations of +20%, +10%, +5%, or +0.1% from the specified value, as such variations are appropriate to in the context of the systems, devices, circuits, methods, and other implementations described herein. “Substantially” as used herein and in the appended claims when referring to a measurable value such as an amount, a temporal duration, a physical attribute (such as frequency), and the like, also encompasses variations of +20%, +10%, +5%, or +0.1% from the specified value, as such variations are appropriate to in the context of the systems, devices, circuits, methods, and other implementations described herein.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A 3D DRAM semiconductor processing method comprising:
depositing a plurality of layers of amorphous or poly-crystalline material over a substrate, to form a film stack;
depositing a metal seed layer adjacent and parallel to an outer surface of the plurality of layers;
annealing the film stack, driving the metal seed layer in a direction generally 8 perpendicular to the plurality of layers of amorphous or poly-crystalline material; and
removing a remaining portion of the metal seed layer.

2. The method of claim 1, wherein the film stack comprises alternating layers of a channel material and a sacrificial material.

3. The method of claim 1, wherein the film stack comprises one or more layers of doped or undoped silicon, carbon, or combinations thereof.

4. The method of claim 3, wherein the film stack comprises one or more layers of a dielectric material.

5. The method of claim 4, wherein the dielectric material comprises silicon oxide, silicon nitride, doped or undoped silicon germanium, or a combination thereof.

6. The method of claim 1, further comprising depositing a capping layer over a top surface of the film stack.

7. The method of claim 1, wherein the metal seed layer is deposited between the substrate and a first layer of the plurality of layers of amorphous or poly-crystalline material.

8. The method of claim 7, further comprising a capping layer disposed over a last layer of the plurality of layers of amorphous or poly-crystalline material, wherein the capping layer comprises a gettering layer.

9. The method of claim 1, wherein the metal seed layer is deposited over a last layer of the plurality of layers of amorphous or poly-crystalline material.

10. The method of claim 9, wherein the substrate comprises a gettering layer.

11. The method of claim 1, further comprising removing the substrate and any seed metal contained in or adjacent to the substrate after annealing, exposing a lower surface of the film stack.

12. The method of claim 11, further comprising bonding a peripheral component to the lower surface.

13. The method of claim 11, further comprising flipping an orientation of the film stack, wherein the lower surface is disposed above an upper surface, prior to removing the substrate.

14. The method of claim 13, further comprising bonding a secondary substrate to an upper surface of the film stack prior to flipping the orientation of the film stack.

15. The method of claim 1, wherein the metal seed layer is deposited at a thickness of about 1 Å to about 100 Å.

16. A 3D DRAM semiconductor processing method comprising:
depositing a plurality of layers of amorphous or poly-crystalline material over a substrate, to form a film stack;
depositing a metal seed layer over the film stack;
depositing a capping layer over the metal seed layer;
annealing the film stack, to drive the metal seed layer in a direction generally perpendicular to the plurality of layers of amorphous or poly-crystalline material; and
removing a remaining portion of the metal seed layer overlying the metal seed layer.

17. The semiconductor processing method of claim 16, further comprising removing the substrate and any seed metal contained in or adjacent to the substrate after annealing, exposing a lower surface of the film stack.

18. The semiconductor processing method of claim 16, wherein at least one of the capping layer and the substrate comprise a gettering layer.

19. A method of forming a three-dimensional dynamic random-access memory (3D DRAM) device, comprising:
providing a substrate to a processing region of a semiconductor processing chamber,
depositing a metal seed layer over the substrate;
depositing a plurality of alternating pairs of an amorphous or poly-crystalline silicon-containing material and a silicon-and-germanium-containing material layer over the metal seed layer, to form a film stack;
annealing the film stack, to form a seed metal layer over the plurality of alternating pairs of the amorphous or poly-crystalline silicon-containing material; and
removing the seed metal layer.

20. The method of claim 19, further comprising depositing a capping layer over the plurality of alternating pairs of the amorphous or poly-crystalline silicon-containing material, wherein the capping layer comprises a gettering layer.
